(19) United States
(12) Patent Application Publication
(10) Pub. No.: US 2002/0031602 A1
(43) Pub. Date: Mar. 14, 2002

(54) Thermal treatment of solution-processed organic electroactive layer in organic electronic device

(76) Inventor: Chi Zhang, Goleta, CA (US)

Correspondence Address: E I DU PONT DE NEMOURS AND COMPANY, LEGAL DEPARTMENT - PATENTS, 1007 MARKET STREET, WILMINGTON, DE, 19898, US

(21) Appl. No.: 09/872,301

(22) Filed: Jun. 1, 2001

Related U.S. Application Data
(60) Provisional application No. 60/212,934, filed on Jun. 20, 2000.

(51) Int. Cl. B05D 5/12; B05D 3/02; B05D 1/36; H01L 33/00; B05D 7/00

(52) U.S. Cl. 427/58; 427/407.1; 427/384; 257/88; 438/28

(57) ABSTRACT

Heat treatment of conductive polymer buffer layers results in increased resistance and thus improved interpixel isolation in polymer light emitting device arrays. Heat treatment of luminescent layers results in improved lifetimes for polymer light emitting device arrays.

### FIELD OF THE INVENTION

This invention related to organic electronic devices and their fabrication. More particularly this invention relates to improvements in manufacturing such devices which can lead to improved lifetimes and/or improved performance of such devices.

### BACKGROUND OF THE INVENTION

Organic electronic devices, such as light emitting devices, photodetecting devices and photovoltaic cells, may be formed of a thin layer of electroactive organic material sandwiched between two electrical contact layers. Electroactive organic materials are organic materials exhibiting electroluminescence, photosensitivity, charge (hole or electron) transport and/or injection, electrical conductivity, and/or exciton blocking. The material may be semiconductive. At least one of the electrical contact layers is transparent to light so that light can pass through the electrical contact layer to or from the electroactive organic material layer. Other devices with similar structures include photoconductive cells, photoresistive cells, photodiodes, photoswitches, transistors, capacitors, resistors, chemoresistive sensors (gas/vapor sensitive electronic noses, chemical and biosensors), writing sensors, and electrochromic devices (smart windows).

Organic electroluminescent materials which emit light upon application of electricity across the electrical contact layers include organic molecules such as anthracene, butadienes, coumarin derivatives, acridine, and stilbene derivatives. See, for example, U.S. Pat. No. 4,356,429 to Tang. Semiconductive conjugated polymers have also been used as electroluminescent materials. See, for example, Friend et al., U.S. Pat. No. 5,247,190, Heeger et al., U.S. Pat. No. 5,408,109, and Nakano et al., Published European Patent Application 443 861. The electroactive organic materials can be tailored to provide emission at various wavelengths.

Light sensitive devices, such as photodetectors and photovoltaic cells, may also use certain conjugated polymers and electro- and photo-luminescent materials to generate an electrical signal in response to radiant energy. Electroluminescent materials mixed with a charge trapping material, such as buckminsterfullerene (C₆₀) and its derivatives, show such light sensitivity. See, for example, Yu, Gang, et al., “photovoltaic cells and photodetectors made with semiconductor polymers: Recent Progress”, Conference 3939, Photonics West, San Jose, Calif., Jan. 22-28, 2000.

Organic electronic devices offer the advantages of flexibility, low cost and ease of manufacture. (Id.) Their performance approaches and in some cases even exceeds that of traditional photosensitive devices. (Id.) Organic electronic devices such as photoemitting, photodetecting and photovoltaic devices typically include a layer of charge injection/transport material adjacent to the electroluminescent organic material to facilitate charge transport (electron or hole transport) and/or gap matching of the electroactive organic material and an electrical contact.

Organic semiconducting material may also be used to form thin film transistors. Transistors may now be fabricated completely from organic materials. Transistors of organic materials are less expensive than traditional transistors and may be used in low end applications where lower switching speeds maybe acceptable and where it would be uneconomical to use traditional transistors. See, for example, Drury, C. J., et al., “Low-cost all-polymer integrated circuits”, Appl. Phys. Lett., vol. 73, No. 1, Jul. 6, 1998, pp. 108-110. In addition, organic transistors may be flexible, which would also be advantageous in certain applications, such as to control light emitting diodes on a curved surface of a monitor. (Id.) Organic semiconducting materials include pentacene, polythienylene vinylene, thiophene oligomers, benzothiophene dimers, phthalocyanines and polyacetylenes. See, for example, U.S. Pat. No. 5,981,970 to Dimitrakopoulos et al., U.S. Pat. No. 5,625,199 to Bauntech, et al., U.S. Pat. No. 5,347,144 to Gamier, et al., and Klauck, Hagen et al., “Deposition: Pentacene organic thin-film transistors and ICs,” Solid State Technology, Vol. 43, Issue 3, March 2, on pp. 63-75.

Electroactive organic materials may be applied to one of the electrical contact layers or onto a portion of a transistor by solution processible methods such as spin-coating, casting or ink-jet printing. Alternatively, these materials may be applied directly by vapor deposition processes, depending on the nature of the materials. In another alternate process an electroactive polymer precursor may be applied and converted to a polymer, typically by heat. Such alternate methods may be complex, slow, expensive, lack sufficient resolution and when patterned using the standard lithographic (wet development) techniques, expose the device to deleterious heat and chemical processes.

In many applications, especially in polymer emissive displays, arrays of light-emitting diodes are assembled. In these applications there is typically a unit body of active polymer and the electrodes are patterned to provide the desired plurality of pixels in the array. With arrays based on a unit body of active polymer and patterned electrodes there is a need to minimize interference or “cross talk” among adjacent pixels. This need has also been addressed by varying the nature of the contacts between the active polymer body and the electrodes.

The desire to improve operating life and efficiency is often seemingly at cross purposes with the desire to minimize cross talk. High efficiency and long operating life are promoted by the use of high conductivity contacts with the active material layer. Cross talk is minimized when the resistance between adjacent pixels is high. Structures which favor high conductivity and thus high efficiency and long operating life are contrary to the conditions preferred for low cross talk.

In U.S. Pat. No. 5,723,873 it is disclosed that it is advantageous to place a hole injection/transport material or buffer layer such as conductive polyaniline (PANI) between the hole-transport/injecting electrode and the layer of active material to increase diode efficiency and to lower the diode's turn on voltage.

Polyaniline in the emeraldine salt form (PANI(ES)) as typically prepared has intrinsically low electrical resistivity. However, for use in pixellated displays, the PANI(ES) or the like buffer layer needs to have a high electrical sheet resistance, otherwise lateral conduction causes cross-talk between neighboring pixels. The resulting inter-pixel current leakage significantly reduces the power efficiency and limits both the resolution and the clarity of the display. U.S. Pat. No. 5,334,539 to Shinar et al describes the use of a 1-24 hour annealing process for completed poly(p-phenyleneacetylene) diode devices to reduce the EL threshold voltage, i.e. the initial voltage at which the device electroluminesces, by about 20% and to improve operating lifetime.

There is a continued need to improve the performance and lifetime of electroactive organic devices.

### SUMMARY OF THE INVENTION

The invention relates to an organic electronic device containing at least one solution-processed organic electroactive material, wherein one or more of the at least one solution-processed organic electroactive material is heat-treated.

The invention also relates to the use of heat treatment to improve the life time and/or performance of an organic electronic device containing at least one layer of solution-processed organic electroactive material, by heat-treating one or more of such solution processed layers.

The invention further relates to a method of making an organic electronic device containing a first electrode, a second electrode, and at least one solution-processed organic electroactive material between the first and second electrodes, wherein the method involves providing one or more of the at least one solution-processed organic electornic material on the first electrode and one or more steps of heat-treating one or more of the solution-processed organic electroactive material before laying down the second electrode.

As used herein, the term “organic electroactive material” refers to any organic material that exhibits the specified electroactivity, such as electroluminescence, photosensitivity, charge transport and/or charge injection, electrical conductivity and exciton blocking. The term “solution-processed organic electroactive material” refers to any organic electroactive material that has been incorporated in a suitable solvent during layer formation in electronic device assembly. The term “charge” when used to refer to charge injection/transport refers to one or both of hole and electron transport/injection, depending upon the context. The term “photoactive” organic material refers to any organic material that exhibits the electroactivity of electroluminescence and/or photosensitivity. The terms “conductivity” and “bulk conductivity” are used interchangeably, the value of which is provided in the unit of Siemens per centimeter (S/cm). In addition, the terms “surface resistivity” and “sheet resistance” are used interchangeably to refer to the resistance value that is a function of sheet thickness for a given material, the value of which is provided in the unit of ohm per square (ohm/sq). Also, the terms “bulk resistivity” and “electrical resistivity” are used interchangeably to refer to the resistivity that is a basic property of a specific materials (i.e., does not change with the dimension of the substance), the value of which provided in the unit of ohm-centimeter (ohm-cm). Electrical resistivity value is the inverse value of conductivity.

### DETAILED DESCRIPTION OF THE INVENTION

### BRIEF DESCRIPTION OF THE DRAWINGS

This invention will be described with reference being made to the drawings.

In these drawings,

FIG. 1 is a cross-sectional view of a representative solid state devices embodying the invention (not-to-scale).

FIG. 2 is a graph which shows the stress induced degradation of a device with PANI(ES) and its blend layer at 70° C.

FIG. 3 is a graph which shows the stress induced degradation of a device from PANI(ES)-PAM blend with different heat treatment at 70° C.

FIG. 4 is a graph which shows the dependence of the conductivity of PANI(ES)-PAM blends on baking time at 200° C.

FIG. 5 is a graph which shows the stress induced degradation of a device with PANI(ES)-PAM blends baked at 200° C. for different time at 70° C.

FIG. 6 is a graph which shows the stress induced degradation of a device with different PANI(ES)-PAM blends at 70° C.

FIG. 7 is a graph which shows the stress induced degradation of a device with C-PPV layer baked at different temperatures.

### DESCRIPTION OF THE PREFERRED EMBODIMENTS

This invention relates generally to the use of thermal treatment of at least one solution-processed organic electroactive layers in an organic electronic device to provide significant improvements in stability and operating life.

### DEVICE CONFIGURATION

While the formulation of the invention is useful in non-pixelated as well as pixelated electronic devices, the advantages are especially applicable in pixelated devices.

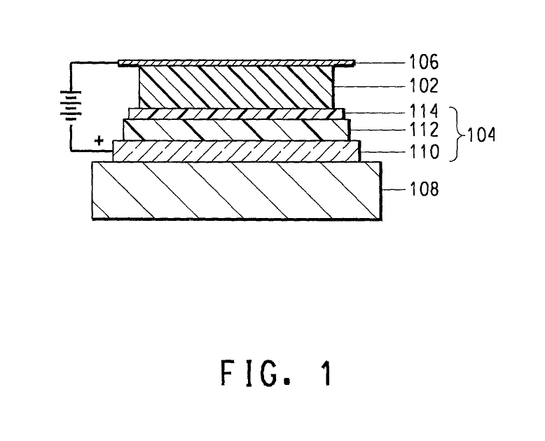

As shown in FIG. 1, each individual pixel of an organic electronic device of the invention includes a cathode layer 106 and an anode layer 110 that is deposited on an optional substrate 108 (also known as the support) and electroactive layers 102, 112 between the cathode 106 and anode 110. Adjacent to the anode 110 is a hole injection/transport layer 112 (also known as the buffer layer). Between the hole injection/transport layer 112 and the cathode 106 is the photoactive layer 102.

The remainder of this description of preferred embodiments is organized according to these various components. More specifically it contains the following sections:

The Photoactive Layer (102)

The Anode (110)

The Buffer Layer (112)

The Cathode (106)

The Substrate (108)

Optional Components

Solution-Processed Organic Electroactive Layers

Fabrication Techniques

The Heat Treatment

Examples

The Photoactive Layer (102)

Depending upon the application of the electronic device, the photoactive layer 102 can be a light-emitting layer that is activated by an applied voltage (such as in a light-emitting diode or light-emitting electrochemical cell), a layer of material that responds to radiant energy and generates a signal with or without an applied bias voltage (such as in a photodetector). Examples of photodetectors include photoconductive cells, photoresistors, photoswitches, phototransistors, and phototubes, and photovoltaic cells, as these terms are describe in Markus, John, Electronics and Nucleonics Dictionary, 470 and 476 (McGraw-Hill, Inc. 1966).

Where the electronic device is a light-emitting device, the photoactive layer 102 will emit light when sufficient bias voltage is applied to the electrical contact layers. Suitable active light-emitting materials include organic molecular materials such asanthracene, butadienes, coumarin derivatives, acridine, and stilbene derivatives, see, for example, Tang, U.S. Pat. No. 4,356,429, Van Slyke et al., U.S. Pat. No. 4,539,507, the relevant portions of which are incorporated herein by reference. Alternatively, such materials can be polymeric materials such as those described in Friend et al. (U.S. Pat. No. 5,247,190), Heeger et al. (U.S. Pat. No. 5,408,109), Nakano et al. (U.S. Pat. No. 5,317,169), the relevant portions of which are incorporated herein by reference. The light-emitting materials may be dispersed in a matrix of another material, with and without additives, but preferably form a layer alone. In preferred embodiments, the electroluminescent polymer comprises at least one conjugated polymer or a co-polymer which contains segments of π-conjugated moieties. Conjugated polymers are well known in the art (see, e.g., Conjugated Polymers, J. -L. Bredas and R. Silbey edt., Kluwer Academic Press, Dordrecht, 1991). Representative classes of materials include, but are not limited to the following:

xxx

(i) poly(p-phenylene vinylene) and its derivatives substituted at various positions on the phenylene moiety;

(ii) poly(p-phenylene vinylene) and its derivatives substituted at various positions on the vinylene moiety;

(iii) poly(arylene vinylene), where the arylene may be such moieties as naphthalene, anthracene, furylene, thienylene, oxadiazole, and the like, or one of the moieties with functionalized substituents at various positions;

(iv) derivatives of poly(arylene vinylene), where the arylene may be as in (iii) above, substituted at various positions on the arylene moiety;

(v) derivatives of poly(arylene vinylene), where the arylene may be as in (iii) above, substituted at various positions on the vinylene moiety;

(vi) co-polymers of arylene vinylene oligomers with non-conjugated oligomers, and derivatives of such polymers substituted at various positions on the arylene moieties, derivatives of such polymers substituted at various positions on the vinylene moieties, and derivatives of such polymers substituted at various positions on the arylene and the vinylene moieties;

(vii) poly(p-phenylene) and its derivatives substituted at various positions on the phenylene moiety, including ladder polymer derivatives such as poly(9,9-dialkyl fluorene) and the like;

(viii) poly(arylenes) and their derivatives substituted at various positions on the arylene moiety,

(ix) co-polymers of oligoarylenes with non-conjugated oligomers, and derivatives of such polymers substituted at various positions on the arylene moieties;

(x) polyquinoline and its derivatives;

(xi) co-polymers of polyquinoline with p-phenylene and moieties having solubilizing function;

(xii) rigid rod polymers such as poly(p-phenylene-2,6-benzobisthiazole), poly(p-phenylene-2,6-benzobisoxazole), poly(p-phenylene-2,6-benzimidazole), and their derivatives; and the like.

More specifically, the light-emitting materials may include but are not limited to poly(phenylenevinylene), PPV, and alkoxy derivatives of PPV, such as for example, poly(2-methoxy-5-(2′-ethyl-hexyloxy)-p-phenylenevinylene) or “MEH-PPV” (U.S. Pat. No. 5,189,136). BCHA-PPV is also an attractive light-emitting material. (C. Zhang, et al, J. Electron. Mater., 22, 413 (1993)). PPPV is also suitable. (C. Zhang et al, Synth. Met., 62, 35 (1994) and references therein.) Luminescent conjugated polymer which are soluble in common organic solvents are preferred since they enable relatively simple device fabrication [A. Heeger and D. Braun, U.S. Pat. No. 5,408,109 and 5,869,350].

Even more preferred light-emitting polymers and copolymers are the soluble PPV materials described in H. Becker et al., Adv. Mater. 12, 42 (2000) and referred to herein as C-PPV's. Blends of these and other semi-conducting polymers and copolymers which exhibit electroluminescence can be used. Where the electronic device 100 is a photodetector, the photoactive layer 102 responds to radiant energy and produces a signal either with or without a biased voltage. Materials that respond to radiant energy and is capable of generating a signal with a biased voltage (such as in the case of a photoconductive cells, photoresistors, photoswitches, phototransistors, phototubes) include, for example, many conjugated polymers and electroluminescent materials. Materials that respond to radiant energy and are capable of generating a signal without a biased voltage (such as in the case of a photoconductive cell or a photovoltaic cell) include materials that chemically react to light and thereby generate a signal. Such light-sensitive chemically reactive materials include for example, many conjugated polymers and electro- and photo-luminescent materials. Specific examples include, but are not limited to, MEH-PPV (“Optocoupler made from semiconducting polymers”, G. Yu, K. Pakbaz, and A. J. Heeger, Journal of Electronic Materials, Vol. 23, pp 925-928 (1994); and MEH-PPV Composites with CN-PPV (“Efficient Photodiodes from Interpenetrating Polymer Networks”, J. J. M. Halls et al. (Cambridge group) Nature Vol. 376, pp. 498-500, 1995). The electroactive organic materials can be tailored to provide emission at various wavelengths.

In some embodiments, the polymeric photoactive material or organic molecular photoactive material is present in the photoactive layer 102 in admixture from 0% to 75% (w, basis overall mixture) of carrier organic material (polymeric or organic molecular). The criteria for the selection of the carrier organic material are as follows. The material should allow for the formation of mechanically coherent films, at low concentrations, and remain stable in solvents that are capable of dispersing, or dissolving the conjugated polymers for forming the film. Low concentrations of carrier materials are preferred in order to minimize processing difficulties, i.e., excessively high viscosity or the formation of gross in homogeneities; however the concentration of the carrier should be high enough to allow for formation of coherent structures. Where the carrier is a polymeric material, preferred carrier polymers are high molecular weight (M.W.>100,000) flexible chain polymers, such as polyethylene, isotactic polypropylene, polyethylene oxide, polystyrene, and the like. Under appropriate conditions, which can be readily determined by those skilled in the art, these macromolecular materials enable the formation of coherent structures from a wide variety of liquids, including water, acids, and numerous polar and non-polar organic solvents. Films or sheets manufactured using these carrier polymers have sufficient mechanical strength at polymer concentrations as low as 1%, even as low as 0.1%, by volume to enable the coating and subsequent processing as desired. Examples of such coherent structures are those comprised of poly(vinyl alcohol), poly(ethylene oxide), poly-para (phenylene terephthalate), poly-para-benzamide, etc., and other suitable polymers. On the other hand, if the blending of the final polymer cannot proceed in a polar environment, non-polar carrier structures are selected, such as those containing polyethylene, polypropylene, poly(butadiene), and the like.

Typical film thicknesses of the photoactive layers range from a few hundred Ångstrom units (200 Å) to several thousand Angstrom units (10,000 Å) (1 Ångstrom unit=10⁻⁸ cm). Although the photoactive layer film thicknesses are not critical, device performance can typically be improved by using thinner films. Preferred thickness are from 300 Å to 5,000 Å.

The Anode (110)

In the device of the invention that contains a photoactive layer, one electrode is transparent to enable light emission from the device or light reception by the device. Most commonly, the anode is the transparent electrode, although the present invention can also be used in an embodiment where the cathode is the transparent electrode.

The anode 110 is preferably made of materials containing a metal, mixed metal, alloy, metal oxide or mixed-metal oxide. Suitable metals include the Group 11 metals, the metals in Groups 4, 5, and 6, and the Group 8-10 transition metals. If the anode is to be light-transmitting, mixed-metal oxides of Groups 12, 13 and 14 metals, such as indium-tin-oxide, are generally used. The IUPAC numbering system is used throughout, where the groups from the Periodic Table are numbered from left to right as 1-18 (CRC Handbook of Chemistry and St Physics, 81^{st} Edition, 2000). The anode 110 may also comprise an organic material such as polyaniline as described in “Flexible light-emitting diodes made from soluble conducting polymer,” Nature vol. 357, pp 477-479 (Jun. 11, 1992).

Typical inorganic materials which serve as anodes include metals such as aluminum, silver, platinum, gold, palladium, tungsten, indium, copper, iron, nickel, zinc, lead and the like; metal oxides such as lead oxide, tin oxide, indium/tin-oxide and the like; graphite; doped inorganic semiconductors such as silicon, germanium, gallium arsenide, and the like. When metals such as aluminum, silver, platinum, gold, palladium, tungsten, indium, copper, iron, nickel, zinc, lead and the like are used, the anode layer must be sufficiently thin to be semi-transparent. Metal oxides such as indium/tin-oxide are typically at least semitransparent.

As used herein, the term “transparent” is defined to mean “capable of transmitting at least about 25%, and preferably at least about 50%, of the amount of light of a particular wavelength of interest”. Thus a material is considered “transparent” even if its ability to transmit light varies as a function of wavelength but does meet the 25% or 50% criteria at a given wavelength of interest. As is known to those working in the field of thin films, one can achieve considerable degrees of transparency with metals if the layers are thin enough, for example in the case of silver and gold below about 300 Å, and especially from about 20 Å to about 250 Å with silver having a relatively colorless (uniform) transmittance and gold tending to favor the transmission of yellow to red wavelengths.

The conductive metal-metal oxide mixtures can be transparent as well at thicknesses up to as high as 2500 Å in some cases. Preferably, the thicknesses of metal-metal oxide (or dielectric) layers is from about 25 to about 1200 Å when transparency is desired.

This layer is conductive and should be low resistance: preferably less than 300 ohms/square and more preferably less than 100 ohms/square.

The Buffer Layer (112)

The buffer layer 112 facilitates hole injection/transport. The buffer layer 112 may include polyaniline (PANI) or an equivalent conjugated conductive polymer such as polypyrole or polythiophene, most commonly in a blend with one or more nonconductive polymers. Polyaniline is particularly useful. Most commonly it is in the emeraldine salt (ES) form. Useful conductive polyanilines include the homopolymer and derivatives usually as blends with bulk polymers (also known as host polymers). Examples of PANI are those disclosed in U.S. Pat. No. 5,232,631. The preferred PANI blend materials for this layer have a bulk conductivity of from about 10⁻⁴ S/cm to 10⁻¹¹ S/cm. More preferred PANI blends have a bulk conductivity of from 10⁻⁵ S/cm to 10⁻⁸ S/cm.

Suitable conductive materials that can be included in the buffer layer 112 include N,N′-diphenyl-N,N′-bis(3-methylphenyl)-[1,1′-biphenyl]-4,4′-diamine (TPD) and bis[4-(N,N-diethylamino)-2-methylphenyl](4-methylphenyl)methane (MPMP), and hole injection/transport polymers such as polyvinylcarbazole (PVK), (phenylmethyl)polysilane, poly(3,4-ethylenedioxythiophene) (PEDOT), and polyaniline (PANI);electron and hole injection/transporting materials such as 4,4′-N,N′-dicarbazole biphenyl (BCP); or light-emitting materials with good electron and hole transport properties, such as chelated oxinoid compounds, such as tris(8-hydroxyquinolato)aluminum (Alq₃).

When the terms “polyaniline” or PANI are used herein, they are used generically to include substituted and unsubstituted materials, as well as any accompanying dopants, particularly acidic materials, used to render the polyaniline conductive.

In general, polyanilines are polymers and copolymers of film and fiber-forming molecular weight derived from the polymerization of unsubstituted and substituted anilines of the Formula I:

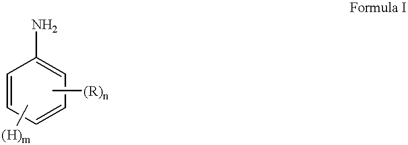

wherein

n is an integer from 0 to 4;

m is an integer from 1 to 5 with the proviso that the sum of n and m is equal to 5; and

R is independently selected so as to be the same or different at each occurrence and is selected from the group consisting of alkyl, alkenyl, alkoxy, cycloalkyl, cycloalkenyl, alkanoyl, alkythio, aryloxy, alkylthioalkyl, alkylaryl, arylalkyl, amino, alkylamino, dialkylamino, aryl, alkylsulfinyl, alkoxyalkyl, alkylsulfonyl, arylthio, arylsulfinyl, alkoxycarbonyl, arylsulfonyl, carboxylic acid, halogen, cyano, or alkyl substituted with one or more sulfonic aid, carboxylic acid, halo, nitro, cyano or epoxy moieties; or carboxylic acid, halogen, nitro, cyano, or sulfonic acid moieties; or any two R groups together may form an alkylene or alkenylene chain completing a 3, 4, 5, 6 or 7-membered aromatic or alicyclic ring, which ring may optionally include one or more divalent nitrogen, sulfur or oxygen atoms. Without intending to limit the scope of this invention, the size of the various R groups ranges from about 1 carbon (in the case of alkyl) through 2 or more carbons up through about 20 carbons with the total of n Rs being from about 1 to about 40 carbons.

Illustrative of the polyanilines useful in the practice of this invention are those of the Formula II to V:

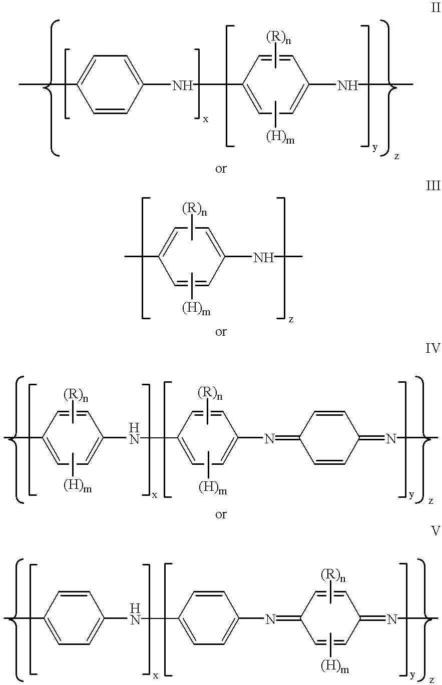

wherein:

n, m and R are as described above except that m is reduced by 1 as a hydrogen is replaced with a covalent bond in the polymerization and the sum of n plus m equals 4;

y is an integer equal to or greater than 0;

x is an integer equal to or greater than 1, with the proviso that the sum of x and y is greater than 1; and

z is an integer equal to or greater than 1.

The following listing of substituted and unsubstituted anilines are illustrative of those which can be used to prepare polyanilines useful in the practice of this invention.

| | |
|---|---|
| Aniline | 2,5-Dimethylaniline |
| o-Toluidine | 2,3-Dimethylaniline |
| m-Toluidine | 2,5-Dibutylaniline |
| o-Ethylaniline | 2,5-Dimethoxyaniline |
| m-Ethylaniline | Tetrahydronaphthylamine |
| o-Ethoxyaniline | o-Cyanoaniline |
| m-Butylaniline | 2-Thiomethylaniline |
| m-Hexylaniline | 2,5-Dichloroaniline |
| m-Octylaniline | 3-(n-Butanesulfonic acid)aniline |
| 4-Bromoaniline | |
| 2-Bromoaniline | |
| 3-Bromoaniline | 2,4-Dimethoxyaniline |
| 3-Acetamidoaniline | 4-Mercaptoaniline |
| 4-Acetamidoaniline | 4-Methylthioaniline |
| 5-Chloro-2-methoxyaniline | 3-Phenoxyaniline |
| 5-Chloro-2-ethoxyaniline | 4-Phenoxyaniline |

Illustrative of useful R groups are alkyl, such as methyl, ethyl, octyl, nonyl, tert-butyl, neopentyl, isopropyl, sec-butyl, dodecyl and the like, alkenyl such as 1-propenyl, 1-butenyl, 1-pentenyl, 1-hexenyl, 1-heptenyl, 1-octenyl and the like; alkoxy such as propoxy, butoxy, methoxy, isopropoxy, pentoxy, nonoxy, ethoxy, octoxy, and the like, cycloalkenyl such as cyclohexenyl, cyclopentenyl and the like; alkanoyl such as butanoyl, pentanoyl, octanoyl, ethanoyl, propanoyl and the like; alkylsulfinyl, alkysulfonyl, alkylthio, arylsulfonyl, arylsulfinyl, and the like, suchas butylthio, neopentylthio, methylsulfinyl, benzylsulfinyl, phenylsulfinyl, propylthio, octylthio, nonylsulfonyl, octylsulfonyl, methylthio, isopropylthio, phenylsulfonyl, methylsulfonyl, nonylthio, phenylthio, ethylthio, benzylthio, phenethylthio, naphthylthio and the like; alkoxycarbonyl such as methoxycarbonyl, ethoxycarbonyl, butoxycarbonyl and the like, cycloalkyl such as cyclohexyl, cyclopentyl, cyclooctyl, cycloheptyl and the like; alkoxyalkyl such asmethoxymethyl, ethoxymethyl, butoxymethyl, propoxyethyl, pentoxybutyl and the like; aryloxyalkyl and aryloxyaryl such as phenoxyphenyl, phenoxymethylene andthe like; and various substituted alkyl and aryl groups such as 1-hydroxybutyl, 1-aminobutyl, 1-hydroxylpropyl, 1-hydyroxypentyl, 1-hydroxyoctyl, 1-hydroxyethyl, 2-nitroethyl, trifluoromethyl, 3,4-epoxybutyl, cyanomethyl, 3-chloropropyl, 4-nitrophenyl, 3-cyanophenyl, and the like; sulfonic acidterminated alkyl and aryl groups and carboxylic acid terminated alkyl and aryl groups such as ethylsulfonic acid, propylsulfonic acid, butylsulfonic acid, phenylsulfonic acid, and the corresponding carboxylic acids.

Also illustrative of useful R groups are divalent moieties formed from any two R groups such as moieties of the formula:

—(CH₂)—_{n*}

wherein n* is an integer from about 3 to about 7, as for example —(CH₂)₋₄,—(CH₂)₋₃ and —(CH₂)₋₅, or such moieties which optionally include heteroatoms of oxygen and sulfur such as —CH₂SCH₂— and —CH₂—O—CH₂—. Exemplary of other useful R groups are divalent alkenylene chains including 1 to about 3 conjugated double bond unsaturation such as divalent 1,3-butadiene and like moieties.

Preferred for use in the practice of this invention are polyanilines of the above Formulas II to V in which:

n is an integer from 0 to about 2;

m is an integer from 2 to 4, with the proviso that the sum of n and m is equal to 4;

R is alkyl or alkoxy having from 1 to about 12 carbon atoms, cyano, halogen, or alkyl substituted with carboxylic acid or sulfonic acid substituents;

x is an integer equal to or greater than 1;

y is an integer equal to or greater than 0. with the proviso that the sum of xand y is greater than about 4, and

z is an integer equal to or greater than about 5.

In more preferred embodiments of this invention, the polyaniline is derived from unsubstituted amline, i.e., where n is 0 and m is 5 (monomer) or 4 (polymer). In general, the number of monomer repeat units is at least about 50.

As described in U.S. Pat. No. 5,232,631, the polyaniline is rendered conductive by the presence of an oxidative or acidic species. Acidic species and particularly “functionalized protonic acids” are preferred in this role. A “functionalized protonic acid” is one in which the counter-ion has been functionalized preferably to be compatible with the other components of this layer. As used herein, a “protonic acid” is an acid that protonates the polyaniline to form a complex with said polyaniline.

In general, functionalized protonic acids for use in the invention are those of Formulas VI and VII:

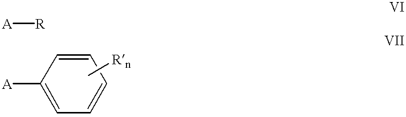

wherein:

A is sulfonic acid, selenic acid, phosphoric acid, boric acid or a carboxylic acid group; or hydrogen sulfate, hydrogen selenate, hydrogen phosphate;

n is an integer from 1 to 5;

R is alkyl, alkenyl, alkoxy, alkanoyl, alkylthio, alkylthioalkyl, having from 1 to about 20 carbon atoms; or alkylaryl, arylalkyl, alkylsulfinyl, alkoxyalkyl, alkylsulfonyl, alkoxycarbonyl, carboxylic acid, where the alkyl or alkoxy has from 0 to about 20 carbon atoms; or alkyl having from 3 to about 20 carbon atoms substituted with one or more sulfonic acid, carboxylic acid, halogen, nitro, cyano, diazo, or epoxy moieties; or a substituted or unsubstituted 3, 4, 5, 6 or 7 membered aromatic or alicyclic carbon ring, which ring may include one or more divalent heteroatoms of nitrogen, sulfur, sulfinyl, sulfonyl or oxygen such as thiophenyl, pyrolyl, furanyl, pyridinyl.

In addition to these monomeric acid forms, R can be a polymeric backbone from which depend a plurality of acid functions “A.” Examples of polymeric acids include sulfonated polystyrene, sulfonated polyethylene and the like. In these cases the polymer backbone can be selected either to enhance solubility in nonpolar substrates or be soluble in more highly polar substrates in which materials such as polymers, polyacrylic acid or poly(vinylsulfonate), or the like, can be used.

R′ is the same or different at each occurrence and is alkyl, alkenyl, alkoxy, cycloalkyl, cycloalkenyl, alkanoyl, alkylthio, aryloxy, alkylthioalkyl, alkylaryl, arylalkyl, alkylsulfinyl, alkoxyalkyl, alkylsulfonyl, aryl, arylthio, arylsulfinyl, alkoxycarbonyl, arylsulfonyl, carboxylic acid, halogen, cyano, or alkyl substituted with one or more sulfonic acid, carboxylic acid, halogen, nitro, cyano, diazo or epoxy moieties; or any two R substituents taken together are an alkylene or alkenylene group completing a 3, 4, 5, 6 or 7 membered aromatic or alicyclic carbon ring or multiples thereof, which ring or rings may include one or more divalent heteroatoms of nitrogen, sulfur, sulfinyl, sulfonyl or oxygen. R′ typically has from about 1 to about 20 carbons especially 3 to 20 and more especially from about 8 to 20 carbons.

Materials of the above Formulas VI and VII are preferred in which:

A is sulfonic acid, phosphoric acid or carboxylic acid;

n is an integer from 1 to 3;

R is alkyl, alkenyl, alkoxy, having from 6 to about 14 carbon atoms; or arylalkyl, where the alkyl or alkyl portion or alkoxy has from 4 to about 14 carbon atoms; or alkyl having from 6 to about 14 carbon atoms substituted with one or more, carboxylic acid, halogen, diazo, or epoxy moieties;

R′ is the same or different at each occurrence and is alkyl, alkoxy, alkylsulfonyl, having from 4 to 14 carbon atoms, or alkyl substituted with one or more halogen moieties again with from 4 to 14 carbons in the alkyl.

Among the particularly preferred embodiments, most preferred for use in the practice of this invention are functionalized protonic acids of the above Formulas VI and VII in which:

A is sulfonic acid;

n is the integer 1 or 2;

R is alkyl or alkoxy, having from 6 to about 14 carbon atoms; or alkyl having from 6 to about 14 carbon atoms substituted with one or more halogen moieties;

R′ is alkyl or alkoxy, having from 4 to 14, especially 12 carbon atoms, or alkyl substituted with one or more halogen, moieties.

Preferred functionalized protonic acids are organic sulfonic acids such as dodecylbenzene sulfonic acid and more preferably poly(2-acrylamido-2-methyl-1 -propanesulfonic acid) (“PAAMPSA”).

The amount of functionalized protonic acid employed can vary depending on the degree of conductivity required. In general, sufficient functionalized protonic acid is added to the polyaniline-containing admixture to form a conducting material. Usually the amount of functionalized protonic acid employed is at least sufficient to give a conductive polymer (either in solution or in solid form).

The polyaniline can be conveniently used in the practice of this invention in any of its physical forms. Illustrative of useful forms are those described in Green, A. G., and Woodhead, A. E., J. Chem. Soc., 101, 1117 (1912) and Kobayashi, et al., J. Electroanl. Chem., 177, 281-91 (1984), which are hereby incorporated by reference. For unsubstituted polyaniline, useful forms include leucoemeraldine, protoemeraldine, emeraldine, nigraniline and tolu-protoemeraldine forms, with the emeraldine form being preferred.

Copending U.S. patent aApplication Ser. No. 60/168,856 of Cao, Y. and Zhang, C. discloses the formation of low conductivity blends of conjugated polymers with non-conductive polymers and is incorporated herein by reference.

The particular bulk polymer or polymers added to the conjugated polymer can vary. The selection of materials can be based upon the nature of the conductive polymer, the method used to blend the polymers and the method used to deposit the layer in the device.

In processes where the layer 112 is provided using a method that is solution-processed, the materials can be blended by dispersing one polymer in the other, either as a dispersion of small particles or as a solution of one polymer in the other. The polymer are typically admixed in a fluid phase and the layer is typically laid out of a fluid phase.

We have had our best results using water-soluble or water-dispensable conjugated polymers together with water-soluble or water-dispensable bulk polymers. In this case, the blend can be formed by dissolving or dispersing the two polymers in water and casting a layer from the solution or dispersion.

Organic solvents can be used with organic-soluble or organic dispensable conjugated polymers and bulk polymers. In addition, blends can be formed using melts of the two polymers or by using a liquid pre-polymer or monomer form of the bulk polymer which is subsequently polymerized or cured into the desired final material.

In those presently preferred cases where the PANI is water-soluble or water dispersable and it is desired to cast the PANI layer from an aqueous solution, the bulk polymer should be water soluble or water dispersible. In such cases, the bulk polymer can be selected from, for example, polyacrylamides (PAM), poly(acrylic acid) (PAA), poly(vinyl pyrrolidone) (PVPd), acrylamide copolymers, cellulose derivatives, carboxyvinyl polymer, poly(ethylene glycols), poly(ethylene oxide) (PEO), poly(vinyl alcohol) (PVA), poly(vinyl methyl ether), polyamines, polyimines, polyvinylpyridines, polysaccharides, and polyurethane dispersions.

In the case where it is desired to cast the layer from a non-aqueous solution or dispersion the bulk polymer may be selected from, for example liquefiable polyethylenes, isotactic polypropylene, polystyrene, poly(vinylalcohol), poly(ethylvinylacetate), polybutadienes, polyisoprenes, ethylenevinylene copolymers, ethylene-propylene copolymers, poly(ethyleneterephthalate), poly(butyleneterephthalate) and nylons such as nylon 12, nylon 8, nylon 6, nylon 6.6 and the like, polyester materials, polyamides such as polyacrylamides and the like.

In those cases where one polymer is being dispersed in the other, the common solubility of the various polymers may not be required.

The relative proportions of the polyaniline and bulk polymer or prepolymer can vary. For each part of polyaniline there can be from 0 to as much as 20 parts by weight of bulk polymer or prepolymer with 0.5 to 10 and especially 1 to 4 parts of bulk material being present for each part of PANI.

Solvents for the materials used to cast this layer are selected to compliment the properties of the polymers.

In the preferred systems, the PANI and bulk polymer are both water-soluble or water-dispersible and the solvent system is an aqueous solvent system such as water or a mixture of water with one or more polar organic materials such as lower oxyhydrocarbons for example lower alcohols, ketones and esters.

These materials include, without limitation, water mixed with methanol, ethanol, isopropanol, acetone methyl ethyl ketone and the like. If desired, a solvent system of polar organic liquids could be used.

In the case of conducting polymers such as PANI and bulk polymers which are not water-soluble or water-dispersible, nonpolar solvents are most commonly used.

Illustrative of useful common nonpolar solvents are the following materials: substituted or unsubstituted aromatic hydrocarbons such as benzene, toluene, p-xylene, m-xylene, naphthalene, ethylbenzene, styrene, aniline and the like; higher alkanes such as pentane, hexane, heptane, octane, nonane, decane and the like; cyclic alkanes such as decaLydronaphthalene; halogenated alkanes such as chloroform, bromoform, dichloromethane and the like; halogenated aromatic hydrocarbons such as chlorobenzene, o-dichlorobenzene, m-dichlorobenzene, p-dichlorobenzene and the like; higher alcohols such as 2-butanol, 1-butanol, hexanol, pentanol, decanol, 2-methyl-1-propanol and the like; higher ketones such as hexanone, butanone, pentanone and the like; heterocyclics such as morpholine; perfluorinated hydrocarbons such as perfluorodecaline, perfluorobenzene and the like.

The thickness of the conjugated polymer layer will be chosen with the properties of the diode in mind. In those situations where the composite anode is to be transparent, it is generally preferable to have the layer of PANI as thin as practically possible bearing in mind that the number of defects in an array increases as film thickness is increased. Typical thicknesses range from about 100 Å to about 5000 Å. When transparency is desired, thicknesses of from about 100 Å to about 3000 Å are preferred and especially about 2000 Å.

With a film thickness of 200 nm or greater, the electrical resistivity of the PANI(ES) blend layer must be greater than or equal to 10⁴ ohm-cm to avoid cross talk and inter-pixel current leakage. Values in excess of 10⁵ ohm-cm are preferred. Even at 10⁵ ohm-cm, there is some residual current leakage and consequently some reduction in device efficiency. Thus, values of approximately 10⁵ to 10⁸ ohm-cm are even more preferred. Values greater than 10⁹ ohm-cm will lead to a significant voltage drop across the injection/buffer layer and therefore should be avoided.

The Cathode (106)

Suitable materials for use as cathode materials are any metal or nonmetal having a lower work function than the first electrical contact layer (in this case, an anode). Materials for the cathode layer 106 (in this case the second electrical contact) can be selected from alkali metals of Group 1 (e.g., Li, Cs), the Group 2 (alkaline earth) metals—commonly calcium, barium, strontium, the Group 12 metals, the rare earths—commonly ytterbium, the lanthanides, and the actinides. Materials such as aluminum, indium and copper, silver, combinations thereof and combinations with calcium and/or barium, Li, magnesium, LiF can be used.

Alloys of low work function metals, such as for example alloys of magnesium in silver and alloys of lithium in aluminum, are also useful. The thickness of the electron-injecting cathode layer ranges from less than 15 Å to as much as 5,000 Å. This cathode layer 106 can be patterned to give a pixellated array or it can be continuous and overlaid with a layer of bulk conductor such as silver, copper or preferably aluminum which is, itself, patterned.

The cathode layer may additionally include a second layer of a second metal added to give mechanical strength and durability.

The Substrate (108)

In most embodiments, the diodes are prepared on a substrate. Typically the substrate should be nonconducting. In those embodiments in which light passes through it, it is transparent. It can be a rigid material such as a rigid plastic including rigid acrylates, carbonates, and the like, rigid inorganic oxides such as glass, quartz, sapphire, and the like. It can also be a flexible transparent organic polymer such as polyester—for example poly(ethyleneterephthalate), flexible polycarbonate, poly (methyl methacrylate), poly(styrene) and the like.

The thickness of this substrate is not critical.

Other Optional Layers (140 and Others Not Shown)

An optional layer 140 including an electron injection/transport material may be provided between the photoactive layer 102 and the cathode 106. This optional layer 140 can function both to facilitate electron injection/transport, and also serve as a buffer layer or confinement layer to prevent quenching reactions at layer interfaces. Preferably, this layer promotes electron mobility and reduces quenching reactions. Examples of electron transport materials for optional layer 140 include metal chelated oxinoid compounds, such as tris(8-hydroxyquinolato)aluminum (Alq₃); phenanthroline-based compounds, such as 2,9-dimethyl-4,7-diphenyl-1,10-phenanthroline (DDPA) or 4,7-diphenyl -1,10-phenanthroline (DPA), and azole compounds such as 2-(4-biphenylyl)-5-(4-t -butylphenyl)-1,3,4-oxadiazole (PBD) and 3-(4-biphenylyl)-4-phenyl-5-(4-t -butylphenyl)-1,2,4-triazole (TAZ), polymers containing DDPA, DPA, PBD, and TAZ moiety and polymer blends thereof, polymer blends containing containing DDPA, DPA, PBD, and TAZ.

It is known to have other layers in organic electronic devices. For example, there can be a layer (not shown) between the buffer layer 112 and the photactive layer 102 to facilitate positive charge transport and/or band-gap matching of the layers, or to function as a protective layer, or to improve the interfacial property. Similarly, there can be additional layers (not shown) between the photoactive layer 102 and the cathode layer 106 to facilitate negative charge transport and/or band-gap matching between the layers, or to function as a protective layer. Layers that are known in the art can be used. In addition, any of the above-described layers can be made of two or more layers. Alternatively, some or all of anode layer 110, the buffer layer 112 the photoactive layer 102, and cathode layer 106, may be surface treated to increase charge carrier transport efficiency. The choice of materials for each of the component layers is preferably determined by balancing the goals of providing a device with high device efficiency.

Solution-Processed Organic Electroactive Layers

In the electronic device of the invention, the photoactive layer 102, hole injection/transport layer 112, and optional electron transport/injection layer can be solution-processed organic electroactive layers.

The term “solution-processed organic electroactive” refers to a layer containing organic material that exhibits electroactivity and is formed or applied using method that includes the step of formulating a solution of the electroactive component in a suitable solvent (a solution processible method). Such layer formation method includes spin-coating, casting, and screen printing, gravure printing, ink jet printing, web coating, precursor polymer processing, and the like, or any combination thereof.

Fabrication Techniques

The various elements of the devices of the present invention can be fabricated by any of the techniques well known in the art, such as solution casting, screen printing, web coating, ink jet printing, sputtering, evaporation, precursor polymer processing, and the like, or any combination thereof.

In the most common approach, the diodes are built up by sequential deposit of layers upon a substrate. In a representative preparation, the anode 110 is laid down first. The anode layer is 110 usually applied by a physical vapor deposition process or spin-cast process. The term “physical vapor deposition” refers to various deposition approaches carried out in vacuo. Thus, for example, physical vapor deposition includes all forms of sputtering, including ion beam sputtering, as well as all forms of vapor deposition such as e-beam evaporation and resistance evaporation. A specific form of physical vapor deposition which is useful is rf magnetron sputtering.

Next, the buffer layer 112 is laid down. The hole injection/transport layer 112 is preferably be applied using spin-coating, casting, and screen printing, gravure printing, ink jet printing, web coating, precursor polymer processing, and the like, or any combination thereof. The layer can also be applied by ink jet printing, thermal patterning, or physical vapor deposition.

Where the buffer layer 112 is a solution-processed organic electroactive layer, water-soluble or water-dispersible material is generally used as the spin-casting medium. In cases where a non-aqueous solvent is called for are used such as toluene, xylenes, styrene, aniline, decahydronaphthalene, chloroform, dichloromethane, chlorobenzenes and morpholine.

Next, the photoactive layer 102 is deposited. The photoactive layer 102 containing the photoactive organic material can be applied from solutions by any conventional means, spin-coating, casting, and screen printing, gravure printing, ink jet printing, web coating, precursor polymer processing, and the like, or any combination thereof. The photoactive organic materials can be applied directly by vapor deposition processes, depending upon the nature of the materials. It is also possible to apply an electroactive polymer precursor and then convert to the polymer, typically by heating.

Where the photoactive layer is a solution-processed organic electroactive layer, the solvent employed is one which will dissolve the polymer and not interfere with its subsequent deposition. Typically, organic solvents are used. These can include halohydrocarbons such as methylene chloride, chloroform, and carbon tetrachloride, aromatic hydrocarbons such as xylene, benzene, toluene, other hydrocarbons such as decaline, and the like. Mixed solvents can be used, as well. Polar solvents such as water, acetone, tetrabydrofuran acids and the like may be suitable. These are merely a representative exemplification and the solvent can be selected broadly from materials meeting the criteria set forth above.

When depositing various polymers or organic materials on a substrate, the solution can be relatively dilute, such as from 0.1 to 20% w in concentration, especially 0.2 to 5% w. Film thicknesses of 400-4000 and especially 500-2000 Å are typically used.

Finally the low work function electron-injecting contact is deposited. The cathode layer 106 is usually applied by a physical vapor deposition process.

These steps can be altered and even reversed if an “upside down” diode is desired.

In some embodiments, one or more of the electroactive layers 102, 112, 140 and the electrodes 106 and 110 can be patterned. It is understood that the pattern may vary as desired. The layers can be applied in a pattern by, for example, positioning a patterned mask or photoresist on the first flexible composite barrier structure prior to applying the first electrical contact layer material. Alternatively, the layers can be applied as an overall layer and subsequently patterned using, for example, a photoresist and wet chemical etching. The hole injection/transport layer can also be applied in a pattern by ink jet printing, lithography or thermal transfer patterning. Other processes for patterning that are well known in the art can also be used.

The Heat Treatment

In accord with the present invention, one or more of the solution-processed organic electroactive layers are heat treated. In the case of the emissive layer, this heat treatment leads to improved stability and the operating life of the device. In the case of the buffer layer(s), the heat treatment lowers its conductivity (increases its resistance) to levels which lead to improved device performance and diminished cross-talk between pixels.

The heat treating of this invention is carried out in any conventional heating environment including ovens, radinent heaters, hot plates or the like. The heat treatment can be carried out in air or in an inert atmosphere such as in nitrogen or in argon or the like. The conditions for heat treatment range from about 20 seconds to about two hours at temperatures of from about 80 to 300° C. As with most thermal treatments the longer times are most commonly used with the lower temperatures and the shorter times with the higher temperatures.

When treating a hole transport/injection layer 112, one measurement of the degree of heat treatment to be applied is the resistance of the layer following heat treatment. In these cases, the heat treatment can be gauged by an increase in resistance of at least about two-fold. Alternatively, a heat treatment can be deemed in the case of a PANI(ES) layer by the achievement of a resistance of the layer which yields a conductivity of less than 10⁻⁴ S/cm, preferably less than 10⁻⁵ S/cm, and more preferably less than 10⁻⁶ S/cm. For example, good results in these ranges are achieved with heat treatments of from about 0.5 minutes to about 90 minutes at 100 to 300° C. and preferably with heat treatments of from about 1.0 minutes to about 60 minutes at 175 to 250° C.

When treating a photoactive layer 102 or the optional electron transport/injection layer, one measurement of the degree of heat treatment to be applied is the extension of device life brought about by the heat treatment. In these cases, the heat treatment can be gauged by an increase in operating life of at least about 50%, preferably at least about 100% and preferably at least about 200%. Typically the heat treatment conditions which provide this increase are somewhat less strenuous than the conditions used for optimal buffer layer treatment. For example, very good results are achieved with heat treatments in the range of 60 to 180 seconds at temperatures of 80 to 250° C. and particularly 75 to 150 seconds at temperatures of 120 to 180° C.

In a preferred embodiment, heat treatment of one or more solution-processed organic electroactive layers takes place before the second electrode is provided on the device. In the illustrated figure, the cathode layer 106 is the second electrode. It is understood that where the device is fabricated in the reverse order so that the cathode is first laid down, the anode layer would be the second electrode.

Where there is more than layer to be heat treated, the layers may be heat-treated sequentially, wherein a first layer is laid down and heat treated before a second layer is laid down and subsequently heat-treated. In this scenario, the first layer is heat-treated twice. Alternatively, the both layers may be laid down so that heat-treatment of both layers occur at the same time. In this alternate second scenario, both layers are heat-treated once.

It will also be appreciated that the structures just described and their fabrication can be altered to include other layers for physical strength and protection, to alter the color of the light emission or sensitivity of the diodes or the like. It will further be appreciated that the present invention is further useful in organic electronic devices including at least one solution-processed organic electroactive layers but do not contain photoactive layers, such as transistors, capacitors, resistors, chemoresistive sensors (gas/vapor sensitive electronic noses, chemical and biosensors), writing sensors, and electrochromic devices (smart window).

The invention will be further described by the following Examples which are presented to illustrate the invention but not to limit its scope.

### EXAMPLES

PANI(ES) solution/dispersion and blends of solutions/dispersion of PANI(ES), shown in Table 1 below and denoted as compositions 200, 202, 204, 206 and 208, were prepared and described in Examples 2, 4, and 5.

TABLE 1

| Solution/ | | Composition |
|---|---|---|
| Dispersion | PANi Blend | (w:w:w) |
| 200 | PANi | 1:0:0 |
| 202 | PANi-PAM-PAAMPSA | 1:0.5:1.5 |
| 204 | PANi-PAM | 1:2:0 |
| 206 | PANi-PAM | 1:3:0 |
| 208 | PANi-PAM-PAAMPSA | 1:1.5:0.5 |

### Example 1

PANI(ES) powder was prepared according to the following reference (Y. Cao, et al, Polymer, 30(1989) 2307). The emeraldine salt (ES) form was verified by the typical green color. HC1 in this reference was replaced by poly(2-acrylamido-2-methyl-1-ropanesulfonic acid (PAAMPSA) (Aldrich). First, 30.5 g (0.022 mole) of 15% PAAMPSA in water (Aldrich) was diluted to 2.3% by adding 170 ml water. While stirring, 2.2 g (0.022M) aniline was added into the PAAMPSA solution. Then, 2.01 g (0.0088M) of ammonium persulfate in 10 ml water was added slowly into the aniline/PAAMPSA solution under vigorous stirring. The reaction mixture was stirred for 24 hours at room temperature. To precipitate the product, PANI(ES), 1000 ml of acetone was added to the reaction mixture. Most of the acetone/water was decanted and then the PANI(ES)-PAAMPSA precipitate was filtered. The resulting gum-like product was washed several times with acetone and dried at 40° C. under dynamic vacuum for 24 hours.

This Example demonstrates the direct synthesis of PANI(ES).

### Example 2

Solution/Dispersion 200 of Table 1 above was prepared.

Four grams (4.0 g) of the PANI(ES) powder as prepared in Example 1 was mixed with 400 g of deionized water in a plastic bottle. The mixture was rotated at room temperature for 48 hours. The solution dispersion was then filtered through a lam polypropylene filter. Different concentrations of PANI(ES) in water were routinely prepared by changing the quantity of PANI(ES) mixed into the water.

This Example demonstrates that PANI(ES) can be dissolved/dispersed in water and subsequently filtered through a 1 μm filter.

### Example 3

Four grams (4.0 g) of polyacrylamide (PAM) (M.W. 5,000,000-6,000,000, Polysciences) was mixed with 400 ml of deionized water in a plastic bottle. The mixture was rotated at room temperature for at least 48 hours. The solution/dispersion was then filtered through a 1 μm polypropylene filter. Different concentrations of PAM were routinely prepared by changing the quantity of PAM dissolved.

This Example demonstrates that PAM can be dissolved/dispersed in water and subsequently filtered through a 1 μm filter.

### Example 4

Solution/Dispersions 202 and 208 of Table 1 above were prepared.

Twenty grams of a PANI(ES) solution as prepared in Example 2 was mixed (at room temperature for 12 days) with 10 g of 1% PAM solution as prepared in Example 3 and 2.0 g of 15% PAAMPSA solution (Aldrich). The solution was then filtered through 0.45 μm polypropylene filters. The weight ratio of PANI(ES):PAM:PAAMPSA in the blend solution was 1:0.5:1.5. Different blend ratios of the PANI(ES):PAM:PAAMPSA blend solutions (including Solution/Dispersion 208 of Table 1 above, with a ratio of 1:1.5:0.5) were prepared by changing the concentrations in the starting solutions.

### Example 5

30 g of a solution as prepared in Example 2 was mixed with 7 g of deionized water and 0.6 g of PAM (M.W. 5,000,000-6,000,000, Polysciences) under stirring at room temperature for 4-5 days. The solution was filtered through a 0.45 μm polypropylene filter. The weight ratio of PANI(ES) to PAM in the blend solution is 1:2. This is Solution/Dispersion 204 shown in Table 1 above.

Blend solutions were also prepared in which the weight ratio of PANI(ES) to PAM was 1:1, 1:1.5, 1:2.5, 1:3 (Solution/Dispersion 206 of Table 1 above), 1:4, 1:5, 1:6 and 1:9, respectively.

### Example 6

Glass substrates were prepared with patterned ITO electrodes. Using the blend solutions 200, 202, 204, 206 and 208 as prepared in Examples 2, 4 and 5, polyaniline blend layers were spin-cast as films on top of the patterned substrates and thereafter, baked at 90° C. in a vacuum oven for 0.5 hour. The films prepared from the materials of Example 4 and 5 were then treated at 200° C. in a dry box for 30 minutes. The resistance between ITO electrodes was measured using a high resistance electrometer. Thickness of the film was measured by using a Dec-Tac surface profiler (Alpha-Step 500 Surface Profiler, Tencor Instruments). Table 2 below shows the conductivity and thickness of PANI(ES) blend films with different blend compositions and heat treatments. As can be seen from Table 2, the conductivity can be controlled over a wide range. After baking at 200° C. for 30 min., the PANI blend had a conductivity of less than 10⁻⁶ S/cm with a thickness of about 2000 Å, which is ideal for use in pixellated displays.

This Example demonstrates that films of the PANI(ES) blends can be prepared win bulk conductivities less than 10⁻⁵ S/cm, and even less than 10⁻⁶ S/cm; i.e. sufficiently low that interpixel current leakage can be limited without need for patterning the PANI(ES) blend film.

TABLE 2
Bulk conductivity of PANI(ES) blends

| Solution/ | Baking | Thickness | Conductivity |
|---|---|---|---|
| Dispersion | Condition | (Å) | (S/cm) |
| 200 | — | 426 | 5.1 × 10⁻⁴ |
| 202 | — | 2030 | 1.4 × 10⁻⁴ |
| 204 | 200° C./30 min | 1986 | 7.4 × 10⁻⁷ |
| 206 | 200° C./30 min | 2134 | 4.4 × 10⁻⁷ |
| 208 | 200° C./30 min | 1636 | 1.2 × 10⁻⁷ |

### Example 7

Light emitting diodes were fabricated using soluble poly(1,4 phenylenevinylene) copolymer (C-PPV) (H. Becker, H. Spreitzer, W. Kreduer, E. Kluge, H. Schenk, I. D. Parker and Y. Cao, Adv. Mater. 12, 42 (2000) as the active semiconducting, luminescent polymer; the thickness of the C-PPV films were 700-900 Å C-PPV emits yellow-green light with emission peak at ˜560 nm. Indium/tin oxide was used as the anode. Polyaniline blend buffer layers were spin-cast on top of the patterned substrates from PANI-PAAMPSA solutions 200, 202, 204, 206 and 208, as prepared in Examples 2, 4, and 5, and thereafter, baked at 90° C. in a vacuum oven for 0.5 hour. The films prepared from materials of Examples 4 and 5 were then treated at 200° C. in a dry box for 30 minutes. The device architecture was ITO/Polyaniline blend/C-PPV/metal. Devices were fabricated using both ITO on glass as the substrate (Applied ITO/glass) and using ITO on plastic, polyethylene teraphthalate, PET, as the substrate (Courtauld's ITO/PET); in both cases, ITO/Polyaniline blend bilayer was the anode and the hole-injecting contact. Devices were made with a layer of either Ca or Ba as the cathode. The metal cathode film was fabricated on top of the C-PPV layer using vacuum vapor deposition at pressures below 1×10⁻⁶ Torr yielding an photoactive layer with area of 3 cm². The deposition was monitored with a STM-100 thickness/rate meter (Sycon Instruments, Inc.). 2,000-5,000 Å of aluminum was deposited on top of the 15 Å of barium layer. For each of the devices, the current vs. voltage curve, the light vs. voltage curve, and the quantum efficiency were measured. The measured operating voltage and efficiencies of the devices with different PANI blend compositions and heat treatment are summarized in the Table 3.

This Example demonstrates that high performance polymer LEDs can be fabricated using high temperature-treated PANI blend layer.

TABLE 3
Performance of devices fabricated with different PANI(ES) blends

| Solution/ | Baking | Performance at 8.3 mA/cm2 | | |
|---|---|---|---|---|
| Dispersion | Condition | V | cd/A | Lm/W |
| 200 | — | 4.1 | 12.4 | 9.4 |
| 202 | — | 5.3 | 11.2 | 6.7 |
| 204 | 200° C./30 min | 5.9 | 12.0 | 7.0 |
| 206 | 200° C./30 min | 6.0 | 10.5. | 5.6 |
| 208 | 200° C./30 min | 5.4 | 11.0 | 6.4 |

### Example 8

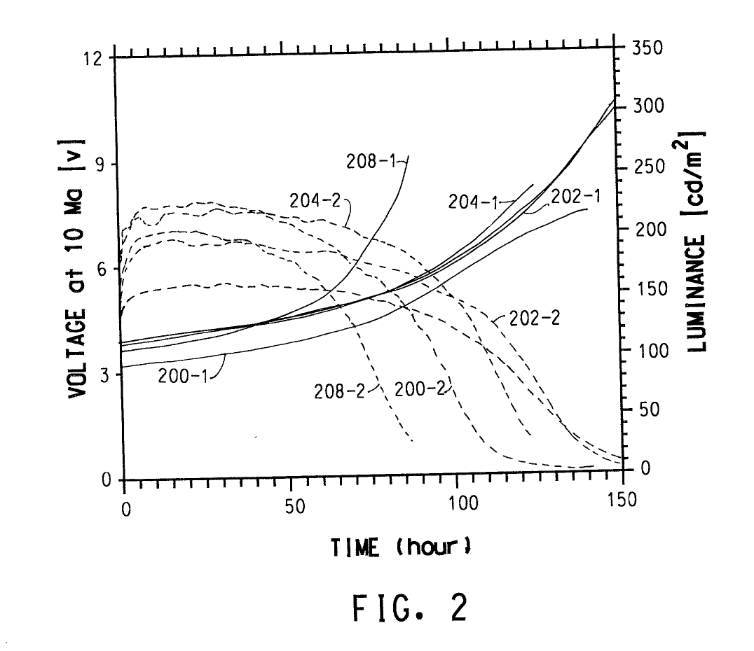

The devices of Example 7 were encapsulated using a cover glass sandwiched by UV-curable epoxy. The encapsulated device were run at a constant current of 3.3 mA/cm² in ambient atmosphere in an oven at 70° C. The total current through the device was 10 mA with luminance of approx. 200 cd/cm². Table 4 below and FIG. 2 shows the light output and voltage increase during operation at 70° C. More specifically, FIG. 2 shows the stress induced degradation of the encapuslated devices, each device containing layer made from Solutions/Dispersions 200, 202, 204, or 208, as denoted in Table 4 below, in the heat-treated hole injection/transport layer. As shown in FIG. 2, the plots shown in solid lines 200-1, 202-1, 204-1, 206-1 and 208-1 for devices containing a layer made from Solutions/Disperions 200, 202, 204, 208 show the voltage measurement for the devices. The plots shown in dashed lines 200-2, 202-2, 204-2, 206-2 and 208-2 for devices containing layer made from Solutions/Dispersion 200, 202, 204, 208 show the luminance of the devices.

In contrast to devices with PANI(ES)-PAM-PAAMPSA blend as anode, which degrade within 50-80 hours of stress at 70° C., the half life of the devices with the PANI(ES)-PAM blend which was baked at 200° C. for 30 minutes exceeds 120 hours with a very low voltage increase (15 mV/hour). It is almost identical to devices with PANI(ES) layers. From Ahrennius plots of the luminance decay and voltage increase data collected at 50, 70 and 85° C., the temperature acceleration factor was estimated to be ca. 25. Thus, the extrapolated stress life at room temperature was determined to be approximately 3,000 hours.

This Example demonstrates that long lifetime can be obtained for polymer LEDS fabricated with PANI(ES) layers that have resistance sufficiently high to avoid inter-pixel current leakage.

TABLE 4
Stress life of devices fabricated with different PANI(ES) blends

| Solution/ | Baking | Stress Life at 70° C. at 3.3 mA/cm2 | | |
|---|---|---|---|---|
| Dispersion | Condition | mV/h | cd/m2* | t112 (h) |
| 200 | — | 12.0 | 224 | 93 |
| 202 | — | 19.2 | 200 | 70 |
| 204 | 200° C./30 min | 15.6 | 222 | 106 |
| 206 | 200° C./30 min | 16.1 | 161 | 117 |
| 208 | 200° C./30 min | 14.9 | 196 | 118 |

*Initial Brightness

### Example 9

The resistance measurements of Example 6 were repeated, but the PANI(ES) layers were spin-cast from the blend solutions 204 shown in Table 1 above, and prepared in Examples 5. The weight ratio of PANI(ES) to PAM in the blend solutions is 1:2. The film was dried in a 90° C. vacuum oven for 0.5 hour and then baked at different temperature and in dry box. Table 5 shows the conductivity of PANI(ES)-blend films with different bake time. As can be seen from the data, the conductivity can be controlled in a wide range, from 10⁻⁴ to 10⁻¹¹ S/cm to meet display requirements. Conductivity values less than 10⁵ S/cm can be obtained by baking the blend film at 200° C. for 30 minutes or longer. With 90 seconds baking at 230° C. or higher, the conductivity dropped below 10⁻¹⁰ S/cm.

This Example demonstrates that PANI(ES)-blend films can be prepared with conductivity values of less than 10⁻⁶ S/cm and even less than 10⁻⁸ S/cm by baking the PANI(ES)-blend at high temperature.

TABLE 5
Bulk conductivity of PANI(ES) blend with different heat treatment

| | Composition | Baking | Conductivity |
|---|---|---|---|
| PANiBlend | (w:w) | Condition | (S/cm) |
| PANi-PAM | 1:2 | — | 4.1 × 10⁻⁵ |
| PANi-PAM | 1:2 | 185° C./5 min | 1.5 × 10⁻⁵ |
| PANi-PAM | 1:2 | 200° C./15 min | 6.7 × 10⁻⁷ |
| PANi-PAM | 1:2 | 200° C./30 min | 8.1 × 10⁻⁷ |
| PANi-PAM | 1:2 | 200° C./60 min | 3.5 × 10⁻⁹ |
| PANi-PAM | 1:2 | 220° C./90 sec | 4.5 × 10⁻⁶ |
| PANi-PAM | 1:2 | 230° C./90 sec | 4.6 × 10⁻¹¹ |
| PANi-PAM | 1:2 | 240° C./90 sec | 1.2 × 10⁻¹¹ |
| PANi-PAM | 1:2 | 250° C./90 sec | 1.1 × 10⁻¹¹ |
| PANi-PAM | 1:2 | 300° C./90 sec | 1.3 × 10⁻¹¹ |
| PANi-PAM | 1:2 | 360° C./90 sec | 1.4 × 10⁻¹¹ |

### Example 10

The device measurements summarized in Example 7 were repeated, but the PANI(ES)-blend layer was prepared as in Examples 9. Table 6 below shows the device performance of LEDs fabricated from PANI-PAM blend with different heat treatment. The optimum heat treatment condition for device performance is at 200° C. for 30 minutes. The device performance deteriorated when PANI(ES)-blend was baked at temperature higher than 200° C.

This Example demonstrates that the heat treated PANI(ES) blends can be used to fabricate polymer LEDs with high performance. The optimum heat treatment condition for device performance is at 200° C. for 30 minutes.

TABLE 6
Performance of devices fabricated from
PANI(ES) blend with different heat treatment#

| | | | Device Performance | | |
|---|---|---|---|---|---|
| | Composition | Baking | at 8.3 mA/cm² | | |
| PANi Blend | (w w) | Condition | V | cd/A | Lm/W |
| PANi-PAM | 1:2 | — | 5.1 | 12.8 | 7.9 |
| PANi-PAM | 1:2 | 185° C./5 min | 5.3 | 12.3 | 7.3 |
| PANi-PAM | 1:2 | 200° C./15 min | 5.0 | 11.5 | 7.1 |
| PANi-PAM | 1:2 | 200° C./30 min | 5.1 | 11.4 | 7.0 |
| PANi-PAM | 1:2 | 200° C./60 min | 5.1 | 10.8 | 6.6 |

#EL polymer = HB974

### Example 11

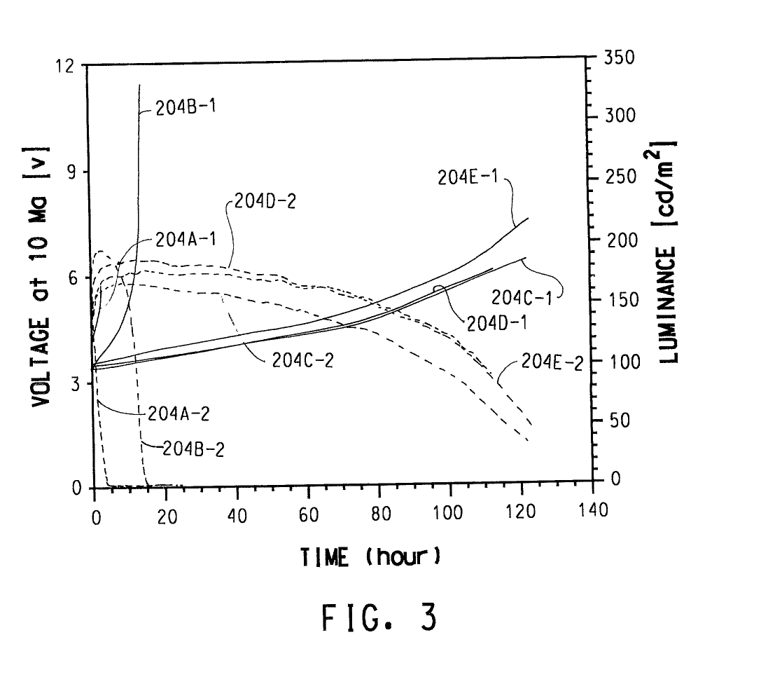

The stress measurements summarized in Example 8 were repeated, but the PANI(ES)-blend layer was prepared as in Examples 9. Table 7 below and FIG. 3 show the stress life time of LEDs fabricated from polyblend films with different heat treatments. More specifically, FIG. 3 shows the stress induced degradation of the encapsulated devices, each device containing a heat-treated layer made from Solution/Dispersion 204 of in Table 1 above, heat-treated at various conditions 204A, 204B, 204B, 204C, 204D, and 204E, as denoted in Table 7 below. As shown in FIG. 3, the plots shown in solid lines 204A-1, 204B-1, 204C-1, 204D-1, 204E-1 show the voltage measurement for the device at heat treatment conditions 204A, 204B, 204B, 204C, 204D, and 204E. The plots shown in dashed lines 204A-2, 204B-2, 204C-2, 204D-2, 204E-2 show the luminance of the device at heat treatment conditions 204A, 204B, 204B, 204C, 204D, and 204E. It can be seen from FIG. 3 that the optimum heat treatment condition for the stress life of the device is 200° C. for 30 minutes.

This Example demonstrates that the heat treated PANI(ES) blends can be used to fabricate polymer LEDs with long stress life. The optimum heat treatment conditions for stress life of the device are 200° C. for 30 minutes.

TABLE 7
Stress life of LED devices fabricated from PANI(ES)
blend 204 with different heat treatment#

| | | Stress Life at | | |
|---|---|---|---|---|
| Heat Treatment | Baking | 70° C. at 3.3 mA/cm2 | | |
| Condition # | Condition | mV/h | cd/m2* | ^{t}1/2^{(h)} |
| 204A | 85° C./30 min | 594 | 162 | 1.6 |
| 204B | 185° C./5 min | 136 | 193 | 12 |
| 204C | 200° C./15 min | 17.0 | 168 | 102 |
| 204D | 200° C./30 min | 16.5 | 178 | 112 |
| 204E | 200° C./60 min | 18.3 | 183 | 110 |

#EL polymer = HB974
*Initial Brightness

### Example 12

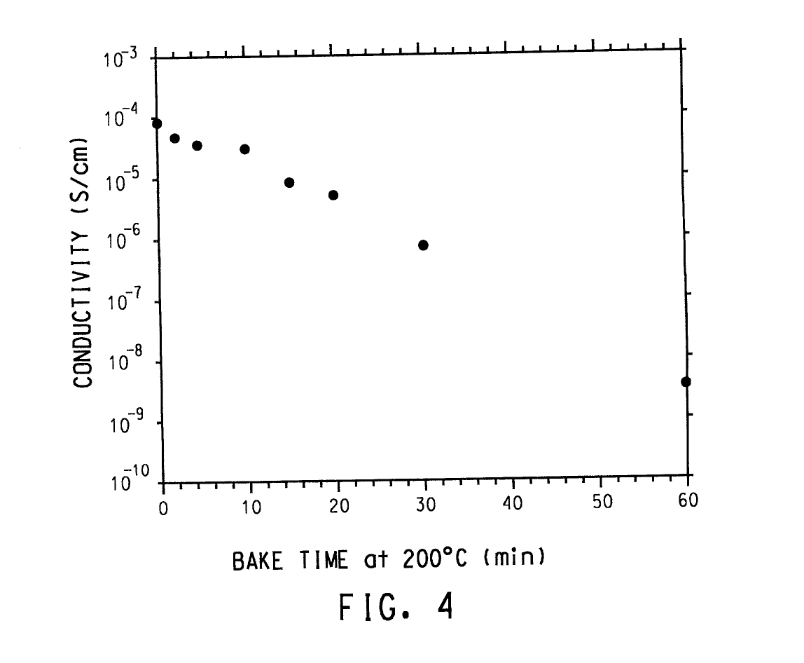

The resistance measurements of Example 6 were repeated, but the PANI(ES) layer was spin-cast from the blend solution 204 of Table 1 above and prepared in Example 5. The weight ratio of PANI(ES) to PAM in the blend solution is 1:2. The blend film was baked at 200° C. for different time in dry box after dried in 90° C. vacuum oven for 0.5 hour. FIG. 4 shows the conductivity of PANI(ES)-blend films with different bake time. As can be seen from the data, the conductivity can be controlled in wide range, from 10⁻⁴ to 10⁻⁸ S/cm to meet display requirements. Conductivity values less than 10⁻⁵ S/cm can be obtained by baking the blend film at 200° C. for 30 minutes or longer. With one hour baking at 200° C., the conductivity dropped below 10⁻⁸ S/cm.

This Example demonstrates that PANI(ES)-blend films can be prepared with conducitivities less than 10⁻⁵ S/cm and even less than 10⁻⁸ S/cm by baking the blend film at 200° C. for different time.

### Example 13

The device measurements summarized in Example 7 were repeated, but the PANI(ES)-blend layer was prepared as in Example 12. Table 8 below shows the device performance of LEDs fabricated from PANI-PAM blends with different baking time at 200° C. The optimum baking time for PANI-PAM blend at 200° C. is 30 minutes.

This Example demonstrates that the heat treated PANI(ES)-PAAMPSA blends can be used to fabricate polymer LEDs with high performance. The optimum heat treatment conditions for device performance are 200° C. for 30 minutes.

TABLE 8
Performance of devices fabricated with PANI(ES)-PAM
blends 204 baked at 200° C. for different time

| | Device Performance at 8.3 mA/cm² | | |
|---|---|---|---|
| Baking Condition | V | cd/A | Lm/W |
| — | 5.0 | 11.4 | 7.1 |
| 200° C./2 min | 4.8 | 12.5 | 8.4 |
| 200° C./5 min | 5.1 | 12.4 | 7.7 |
| 200° C./10 min | 5.1 | 13.2 | 8.1 |
| 200° C./15 min | 5.3 | 11.2 | 7.1 |
| 200° C./20 min | 5.4 | 12.0 | 6.9 |
| 200° C./30 min | 5.6 | 13.3 | 7.4 |
| 200° C./60 min | 5.1 | 10.8 | 6.6 |

### Example 14

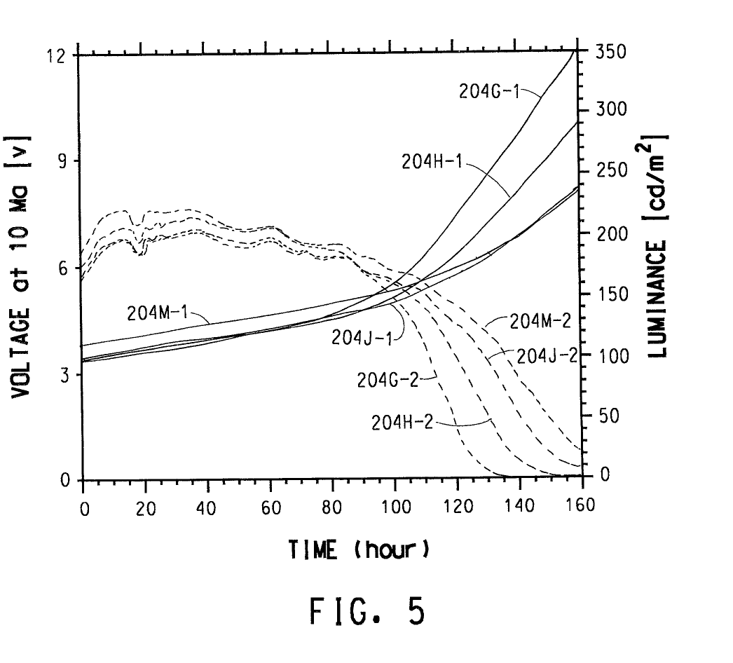

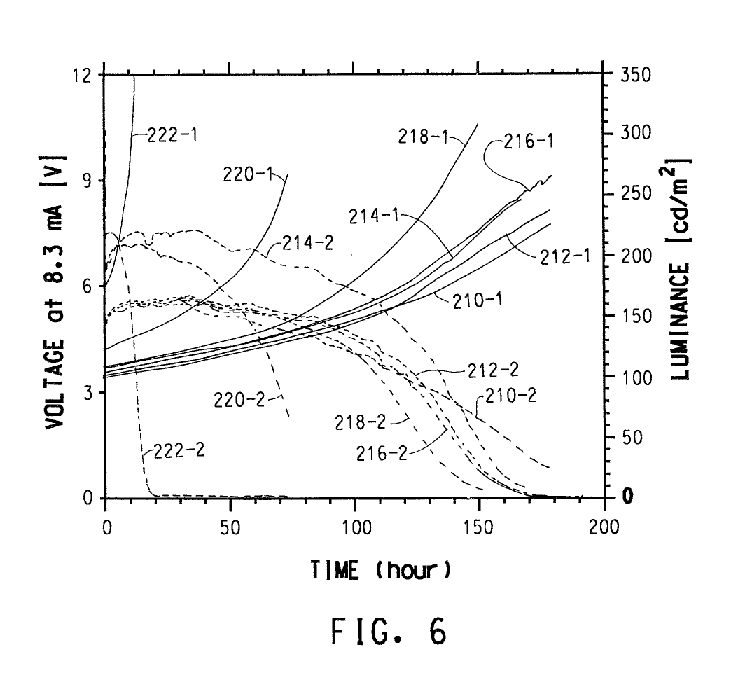

The stress measurements summarized in Example 8 were repeated, but the PANI(ES)-blend layer was prepared as in Example 12 (using Dispersion/Solution 204 of Table 1 above). Table 9 below and FIG. 5 show stress life of LEDs fabricated from polyblend films with different baking time at 200° C. These various baking conditions are labelled 204F through 204N per Table 9 below. More specifically, FIG. 5 shows the stress induced degradation of the encapsulated devices, each device containing a heat-treated layer made from Solution/Dispersion 204 of in Table 1 above, heat-treated at various conditions 204G, 204H, 204J, and 204M as denoted in Table 9 below. As shown in FIG. 5, the plots shown in solid lines 204G-1, 204H-1, 204J-1, and 204M-1 show the voltage measurement for the device at heat treatment conditions 204G, 204H, 204J, and 204M. The plots shown in dashed lines 204G-2, 204H-2, 204J-2, and 204M-2 show the luminance of the device at heat treatment 204G, 204H, 204J, and 204M. It can be seen from FIG. 6 that the optimum heat treatment conditions for the stress life of the device are 200° C. for 30 minutes.

This Example demonstrates that the heat treated PANI(ES) blends can be used to fabricate polymer LEDs with long stress life.

TABLE 9
Stress life of LED devices fabricated with PANI(ES)-PAM
blends 204 baked at 200° C. for different time

| | | Stress Life at | | |
|---|---|---|---|---|
| Baking | Baking | 70° C. at 3.3 mA/cm² | | |
| Condition # | Condition | mV/h | cd/m2* | ^{t}1/2^{(h)} |
| 204F | — | 594 | 162 | 1.6 |
| 204G | 200° C./2 min | 13.8 | 207 | 110 |
| 204H | 200° C./5 min | 13.6 | 213 | 116 |
| 204J | 200° C./10 min | 12.9 | 202 | 128 |
| 204K | 200° C./15 min | 15.8 | 213 | 113 |
| 204L | 200° C./20 min | 16.7 | 238 | 110 |
| 204M | 200° C./30 min | 14.2 | 217 | 133 |
| 204N | 200° C./60 min | 18.3 | 184 | 110 |

*Initial Brightness

### Example 15

The resistance measurements of Example 6 were repeated, but the PANI(ES) layer was spin-cast from the blend solutions prepared in Example 5. The weight ratio of PANI(ES) to PAM in the blend is 1:1,1:1.5,1:2,1:2.5, 1:3, 1:4, 1:5, 1:6 and 1:9, respectively. The film was baked at 200° C. for 30 minutes in a dry box after having dried in a 90° C. vacuum oven for 0.5 hour. Table 10 shows the conductivity of PANI(ES)-blend films with different PANI(ES) to PAM ratios. As can be seen from the data, the conductivity can be controlled in wide range, from 10⁻⁴ to 10⁻⁸ S/cm to meet display requirements. Conductivity values less than 10⁻⁵ S/cm can be obtained by adjusting the PANI(ES) to PAM ratio to 1:1.5 or lower. With the PANI(ES) to PAM ratio of 1:9, the conductivity dropped below 10⁻⁷ S/cm.

This Example demonstrates that PANI(ES)-blend films can be prepared with conductivities less than 10⁻⁵ S/cm and even less than 10⁻⁷ S/cm by adjusting the PANI(ES) to PAM ratio in the blend.

TABLE 10
Bulk conductivity of different PANI(ES)-PAM blends

| | Composition | | Conductivity |
|---|---|---|---|
| PANi Blend | (w:w) | Baking Condition | (S/cm) |
| PANi-PAM | 1:1 | 200° C./30 min | 3.8 × 10⁻⁴ |
| PANi-PAM | 1:1.5 | 200° C./30 min | 5.3 × 10⁻⁶ |
| PANi-PAM | 1:2 | 200° C./30 min | 7.4 × 10⁻⁷ |
| PANi-PAM | 1:2.5 | 200° C./30 min | 6.1 × 10⁻⁷ |
| PANi-PAM | 1:3 | 200° C./30 min | 4.9 × 10⁻⁷ |
| PANi-PAM | 1:4 | 200° C./30 min | 4.6 × 10⁻⁷ |
| PANi-PAM | 1:5 | 200° C./30 min | 4.5 × 10⁻⁷ |
| PANi-PAM | 1:6 | 200° C./30 min | 4.4 × 10⁻⁷ |
| PANi-PAM | 1:9 | 200° C./30 min | 7.5 × 10⁻⁸ |

### Example 16

The device measurements summarized in Example 7 were repeated, but the PANI(ES)-blend layer was prepared as in Example 15. Table 11 shows the device performance of LEDs fabricated from polyblend films with different the PANI(ES) to PAM ratios. These data show that the optimum PANI(ES) to PAM ratio is 1:2 (Device 214). The lower PANI(ES) to PAM ratio results in deterioration of device performance.

This Example demonstrates that the heat treated PANI(ES)-PAM blends can be used to fabricate polymer LEDs with high performance.

TABLE 11
Performance of devices fabricated with different PANI(ES)-PAM
blends

| | | | Device Performance at | | |
|---|---|---|---|---|---|
| | Composition | Baking | 8.3 ma/cm² | | |
| PANi Blend | (w:w) | Condition | V | cd/A | Lm/W |
| PANi-PAM | 1:1 | 200° C./30 min | 5.0 | 9.1 | 5.7 |
| PANi-PAM | 1:1.5 | 200° C./30 min | 5.1 | 11.4 | 7.1 |
| PANi-PAM | 1:2 | 200° C./30 min | 5.6 | 13.3 | 7.4 |
| PANi-PAM | 1:2.5 | 200° C./30 min | 5.5 | 11.8 | 6.8 |
| PANi-PAM | 1:3 | 200° C./30 min | 6.1 | 9.7 | 5.0 |
| PANi-PAM | 1:4 | 200° C./30 min | 6.3 | 12.1 | 6.1 |
| PANi-PAM | 1:5 | 200° C./30 min | 8.4 | 11.4 | 4.4 |
| PANi-PAM | 1:6 | 200° C./30 min | 9.9 | 11.1 | 3.5 |
| PANi-PAM | 1:9 | 200° C./30 min | 19.0 | 5.4 | 0.95 |

### Example 17

The stress measurements summarized in Example 8 were repeated, but the PANI(ES)-blend layer was prepared as in Example 15. As shown in Table 12 below, these devices are labelled 210, 212, 214, 216, 218, 220, 222, 224, and 226. Table 12 below and FIG. 6 show stress life of LEDs fabricated from polyblend films with different PANI(ES) to PAM ratios. As shown in FIG. 6, solid lines 210-1, 212-1, 214-1, 216-1, 218-1, 220-1, and 222-1 for Devices 210, 212, 214, 216, 218, 220 and 222 show the voltage measurement for the devices. The plots shown in dashed lines 210-2, 212-2, 214-2, 216-2, 218-2, 220-2, and 222-2 for Devices 210, 212, 214, 216, 218, 220 and 222 show the luminance measurement for the devices. These data show that the optimum PANI(ES) to PAM ratio for the stress life of the devices 1:2

This Example demonstrates that the heat treated PANI(ES blends can be used to fabricate polymer LEDs with long stress life.

TABLE 12
Stress life of LED devices different fabricated with different
PANI(ES)-PAM blends.

| | | Composition | | Stress Life at 70° C. at 3.3 mA/cm2 | | |
|---|---|---|---|---|---|---|
| Device | PANi Blend | (w:w) | Baking Condition | mV/h | cd/m2* | ^{t}1/2 ^{(h)} |
| 210 | PANi-PAM | 1:1 | 200° C./30 min | 15.0 | 160 | 140 |
| 212 | PANi-PAM | 1:1.5 | 200° C./30 min | 13.4 | 165 | 131 |
| 214 | PANi-PAM | 1:2 | 200° C./30 min | 14.2 | 218 | 133 |
| 216 | PANi-PAM | 1:2.5 | 200° C./30 min | 14.2 | 163 | 124 |
| 218 | PANi-PAM | 1:3 | 200° C./30 min | 18.4 | 162 | 118 |
| 220 | PANi-PAM | 1:4 | 200° C./30 min | 36.4 | 210 | 69 |
| 222 | PANi-PAM | 1:5 | 200° C./30 min | 325 | 220 | 13 |
| 224 | PANi-PAM | 1:6 | 200° C./30 min | 1754 | 210 | 2.4 |
| 226 | PANi-PAM | 1:9 | 200° C./30 min | 7960 | 185 | 1.6 |

*Initial Brightness

### Example 18

The device measurements summarized in Example 7 were repeated, but C-PPV layer was baked at 90° C., 120° C., 150° C., 150° C. and 200° C. for 90 seconds in dry box. Table 13 shows the device performance of LEDs fabricated from C PPV film baked at different temperatures. Baking of C-PPV film at elevated temperature results in lower operation voltage as well as lower light output compared to device made with un-baked C-PPV film.

This Example demonstrates that the thermal treated C-PPV film can be used to fabricate polymer LEDs with high performance.

TABLE 13
Performance of devices with C-PPV layer baked at different temperature

| | Composition | Luminescent Layer | Device Performance at 8.3 mA/cm2 | | |
|---|---|---|---|---|---|
| PANi Blend | (w:w) | Baking Condition | V | cd/A | Lm/W |
| PANi-PAM | 1:2 | — | 6.0 | 6.9 | 3.6 |
| PANi-PAM | 1:2 | 90° C./90 sec | 5.6 | 5.9 | 3.3 |
| PANi-PAM | 1:2 | 120° C./90 sec | 5.6 | 5.9 | 3.3 |
| PANi-PAM | 1:2 | 150° C./90 sec | 5.1 | 5.4 | 3.4 |
| PANi-PAM | 1:2 | 175° C./90 sec | 5.1 | 7.2 | 4.4 |
| PANi-PAM | 1:2 | 200° C./90 sec | 4.6 | 6.7 | 4.5 |

### Example 19

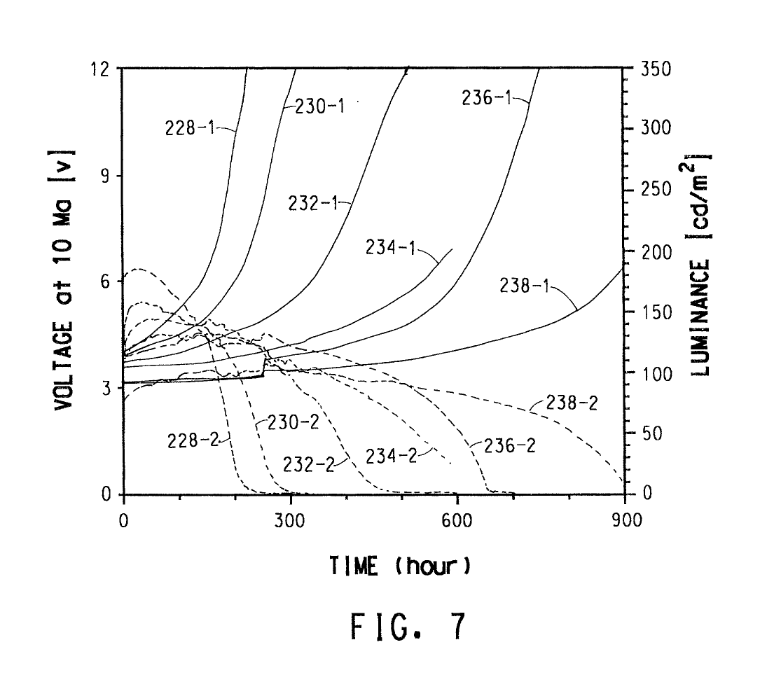

The stress measurements summarized in Example 8 were repeated, but the C-PPV layer was prepared as in Example 18. As shown in Table 14 below, these devices are labelled 228, 230, 232, 234, 236, and 238. Table 14 and FIG. 7 shows stress life of LEDs fabricated from C-PPV film baked at different temperatures. As shown in FIG. 7, solid lines 228-1, 230-1, 232-1, 234-1, 236-1, and 238-1, for Devices 228, 230, 232, 234, 236, and 238 show the voltage measurement for the devices. The plots shown in dashed lines lines 228-2, 230-2, 232-2, 234-2, 236-2, and 238-2, for Devices 228, 230, 232, 234, 236, and 238 show the luminance measurement for the devices As can be seen from the data, the voltage increase rate decreases dramatically after C-PPV film was baked at elevated temperatures. It can drop to 0.9 mV/h after C-PPV film baked at 200° C. for 90 seconds. The half life time of the device with baked (C-PPV film increased 2 to 3 times compared to device with un-baked C-PPV film.

This Example demonstrates that the heat-treated luminescent polymer layer can improve the stress life of the device by 2 to 3 times. The optimum baking condition of C-PPV for the stress life of the device is 150° C. for 90 seconds.

TABLE 14
Stress life of LED devices with C-PPV layer baked at
different temperature

| | | | Luminiescent | | | |
|---|---|---|---|---|---|---|
| | | | Layer | | | |
| | | Composition | Baking | Stress Life at 70° C. at 3.3 mA/cm² | | |
| Device | PANi Blend | (w:w) | Condition | mV/h | cd/m2* | ^{t}/2 ^{(h)} |
| 228 | PANi-PAM | 1:2 | — | 11.3 | 184 | 171 |
| 230 | PANi-PAM | 1:2 | 90° C./90 sec | 7.3 | 157 | 221 |
| 232 | PANi-PAM | 1:2 | 120° C./90 sec | 3.6 | 142 | 356 |
| 234 | PANi-PAM | 1:2 | 150° C./90 sec | 1.9 | 129 | 498 |
| 236 | PANi-PAM | 1:2 | 175° C./90 sec | 1.4 | 129 | 587 |
| 238 | PANi-PAM | 1:2 | 200° C./90 sec | 0.9 | 101 | 780 |

#EL polymer = HB990
* Initial Brightness

What is claimed is:

1. An organic electronic device comprising at least one photoactive layer and at least one hole injection/transport layer, wherein one or more of the at least one photoactive layer is a solution-processed organic electroactive material, wherein said solution-processed organic electroactive material has been heat-treated.

2. An organic electronic device comprising at least one photoactive layer and at least one hole injection/transport layer, wherein:
one or more of the at least one photoactive layer is a first solution-processed organic electroactive material;
one or more of the at least one buffer layer is a second solution-processed organic electroactive material; and
wherein at least one of said first solution-processed organic electroactive material and said second solution-processed organic electroactive material has been heat-treated.

3. An organic electronic device comprising at least one electron injection/transport layer and at least one hole injection/transport layer, wherein:
one or more of the at least one one hole injection/transport layer is a second solution-processed organic electroactive material;
one or more of the at least one electron injection/transport layer is a third solution-processed organic electroactive material; and
wherein at least one of said second solution-processed organic electroactive material, and said third solution-processed organic electroactive material has been heat-treated.

4. The device of claim 3, wherein one or more of the second solution-processed organic electroactive material has been heat-treated.

5. The device of claim 3, wherein one or more of the third solution-processed organic electroactive material has been heat-treated.

6. The device of 3 wherein one or more of the second solution-processed organic electroactive material has been heat-treated at a temperature and for a period which results in at least a doubling of resistance of the hole injection/transport layer.

7. The device of 3 wherein the hole injection/transport layer has been heat-treated at a temperature and for a period which results in a conductivity of less than 10⁻⁶ S/cm.

8. The device of 4 wherein the second solution-processed organic electroactive material is polyaniline.

9. The device of 4 wherein the second solution-processed organic electroactive material is polyaniline in the emeraldine salt form.

10. The device of 3 wherein the hole injection/transport layer has been heat-treated at a temperature of from about 100° C. to about 300° C. for a time period of from about 0.5 minutes to about 90 minutes.

11. The device of claim 2 wherein the photoactive layer has been heat-treated.

12. The device of claim 2, wherein the photoactive layer has been heat-treated at a temperature and for a period which results in an increase in diode operating life of at least about 50%.

13. The device of claim 2, wherein the first solution-processed electroactive material is an electroluminescent conjugated organic polymer.

14. The device of claim 2, wherein the photoactive layer has been heat-treated at a temperature of from about 80° C. to about 250° C. for a time period of from about 1 minute to about 3 minutes.

15. A polymer light-emitting diode comprising in serial order an electron-injecting layer, an emissive polymer layer, a conductive buffer layer comprising conductive conjugated organic polymer that has been heat-treated at a temperature and of a period which results in a conductivity of less than 10⁻⁶ S/cm.

16. A polymer light-emitting diode comprising in serial order an electron-injecting layer, an emissive polymer layer that has been heat-treated, a conductive buffer layer comprising conductive conjugated organic polymer.

17. A method for preparing a organic electronic device comprising the steps of:
a. depositing a conductive electrical contact layer on a solid substrate,
b. depositing a buffer layer comprising a solution-processed organic electroactive material on said conductive electrical contact layer,
c. heat-treating said buffer layer,
d. depositing an photoactive layer onto the heat-treated buffer layer, and
e. depositing an electron-injecting layer onto the photoactive layer.

18. The method of claim 17 wherein the heat-treating is at a temperature and for a period which results in a conductivity of the buffer layer of less than 10⁻⁶ S/cm.

19. The method of claim 17 wherein the solution-processed organic electroactive material is polyaniline.

20. The method of claim 17 wherein the solution-processed organic electroactive material is polyaniline in the emeraldine salt form.

21. The method of claim 17 wherein the heat-treating is carried out at a temperature of from about 100° C. to about 300° C. for a time period of from about 0.5 minutes to about 90 minutes.

22. A method for making an organic electronic device comprising the steps of:
a. depositing a conductive electrical contact layer on a solid substrate,
b. optionally depositing a buffer layer comprising conductive conjugated organic polymer on said conductive electrical contact layer,
c. depositing an photoactive layer on said buffer layer,
d. heat-treating said photoactive layer and the buffer layer, and
e. depositing an electron-injecting layer onto the heat-treated photoactive layer.

23. The method of claim 22 wherein the emissive polymer layer is heat-treated at a temperature and for a period which results in an increase in diode operating life of at least about 50%.

24. The method of claim 22 wherein the emissive polymer layer comprises an electroluminescent conjugated organic polymer.

25. The method of claim 22 wherein the emissive polymer layer is heat-treated at a temperature of from about 80° C. to about 250° C. for a time period of from about 1 minute to about 3 minutes.

26. A method for preparing an organic electronic device comprising the steps of:
a. depositing a conductive electrical contact layer on a solid substrate,
b. optionally depositing a buffer layer comprising solution-processed organic electroactive material on said conductive electrical contact layer,
c. optionally heat-treating said buffer layer,
d. depositing an photoactive layer onto the heat-treated buffer layer,
e. heat-treating the photoactive layer, and
f. depositing an electron-injecting layer onto the photoactive layer.

27. The method of claim 26 wherein the heat-treating of the buffer is at a temperature and for a period which results in a conductivity of the buffer layer of less than 10⁻⁶ S/cm.

28. The method of claim 25 wherein the solution-processed organic electroactive material is polyaniline.

29. The method of claim 26 wherein the solution-processed organic electroactive material is polyaniline in the emeraldine salt form.

30. The method of claim 26 wherein the heat-treating of the buffer layer is carried out at a temperature of from about 100° C. to about 300° C. for a time period of from about 0.5 minutes to about 90 minutes.

31. A method for making an organic electronic device comprising the steps of:
a. depositing a conductive electrical contact layer on a solid substrate,
b. optionally depositing a buffer layer comprising solution-processed organic electroactive material on said conductive electrical contact layer,
c. depositing an photoactive layer onto the heat-treated buffer layer, and
d. depositing an electron-injecting layer onto the emmisive layer, and
e. heat treating the resulting structure.

32. A method of claim 31 wherein the heat-treating of the buffer is at a temperature and for a period which results in a conductivity of the buffer layer of less than 10⁻⁶ S/cm.

33. The method of claim 31 wherein the solution-processed organic electroactive material is polyaniline.

34. The method of claim 31 wherein the solution-processed organic electroactive material is polyaniline in the emeraldine salt form.

35. The method of claim 31 wherein the heat-treating of the buffer layer is carried out at a temperature of from about 100° C. to about 300° C. for a time period of from about 0.5 minutes to about 90 minutes.

36. A method for making an organic electronic device comprising the steps of:
a. depositing an electron-injecting layer onto a solid substrate,
b. depositing an photoactive layer onto the electron-injecting layer,
c. heat-treating said photoactive layer,
d. optionally depositing a buffer layer comprising solution-processed organic electroactive material on the heat-treated photoactive layer, and
e. depositing a hole-injecting layer onto the optional buffer layer where present or on the heat-treated photoactive layer.

37. A method for preparing an organic electronic device comprising the steps of:
a. depositing an electron-injecting layer onto a solid substrate,
b. depositing an photoactive layer onto the electron-injecting layer
c. optionally depositing a buffer layer comprising solution-processed organic electroactive material on the photoactive layer,
d. optionally heat-treating said buffer layer, and
e. depositing a hole-injecting layer onto the optional buffer layer where present or the photoactive layer.

38. A method for making an organic electronic device comprising the steps of:
a. depositing an electron-injecting layer onto a solid substrate,
b. depositing an photoactive layer onto the electron-injecting layer
c. heat-treating said photoactive layer,
d. depositing a buffer layer comprising solution-processed organic electroactive material on the heat-treated photoactive layer,
e. heat-treating the buffer layer, and depositing a hole-injecting layer onto the heat-treated buffer layer.

39. A method for making an organic electronic device containing a first electrode, a second electrode, and at least one electroactive layer between the first and second electrodes, the steps comprising:
a. providing the first electrode;
b. providing the at least one electroactive layer, one or more of said at least one electroactive layer is a solution-processed organic electroactive layer;
c. heat-treating one or more of the solution-processed electroactive layer;
and
d. providing the second electrode.

40. The device of claim 1, wherein the device is a photoconductive cell.

41. The device of claim 1, wherein the device is a photoresistive cell.

42. The device of claim 1, wherein the device is a photoswitch.

43. The device of claim 1, wherein the device is a transistor.

44. The device of claim 1, wherein the device is a photodetecting device.

45. The device of claim 1, wherein the device is a photovoltaic cell.

46. The device of claim 1, wherein the device is a capacitor.

47. The device of claim 1, wherein the device is a resistor.

48. The device of claim 1, wherein the device is a chemoresistive sensor.

49. The device of claim 1, wherein the device is a writing sensor.

50. The device of claim 1, wherein the device is an electrochromic device.
